(19) United States
(12) Patent Application Publication
(10) Pub. No.: US 2026/0136948 A1
(43) Pub. Date: May 14, 2026

(54) Substrate Clip with Sheet and Patterned Electrically Conductive Structure Having Different Thicknesses

(71) Applicant: Infineon Technologies Austria AG, Villach (AT)

(72) Inventors: Yi Ting Tan, Taman Tehel Impian (MY); Chwee Pang Tommy Khoo, Bukit Rambai (MY); Mei Fen Hiew, Taman Paya Rumput Utama (MY); Bee Kwan Saw, Melaka Tengah (MY); Wei Han Koo, Malim (MY)

(21) Appl. No.: 19/383,920

(22) Filed: Nov. 10, 2025

(30) Foreign Application Priority Data
Nov. 12, 2024 (DE) 102024133085.6

(51) Int. Cl. H01L 23/00; H01L 23/495; H01L 25/065

(52) U.S. Cl. CPC H10W 70/417; H10W 72/01653; H10W 72/01661; H10W 72/623; H10W 72/646; H10W 90/00; H10W 90/767

(57) ABSTRACT

A substrate clip for connecting a carrier with an electronic component of a package includes an electrically insulating and thermally conductive sheet and a patterned electrically conductive structure on a main surface of the electrically insulating and thermally conductive sheet. The patterned electrically conductive structure has at least two different connection sections having different thicknesses.

### TECHNICAL FIELD

Various embodiments relate generally to a substrate clip, a package, and a method of manufacturing a substrate clip.

### BACKGROUND

Packages may be denoted as for instance encapsulated electronic components with exposed electrical connections and being mountable on an electronic periphery, for instance on a printed circuit board.

Packaging cost is an important driver for the industry. Related with this are performance, dimensions and reliability. The different packaging solutions are manifold and have to address the needs of the application.

### SUMMARY

There may be a need for a package and corresponding constituents which can be manufactured in a simple way and with high reliability.

According to an exemplary embodiment, a substrate clip for connecting a carrier with an electronic component of a package is provided, wherein the substrate clip comprises an electrically insulating and thermally conductive sheet, and a patterned electrically conductive structure on a main surface of the electrically insulating and thermally conductive sheet and having at least two different connection sections having different thicknesses.

According to another exemplary embodiment, a package is provided which comprises a carrier, an electronic component mounted on the carrier, and a substrate clip having the above mentioned features connecting the carrier with the electronic component, wherein at least one of the at least two different connection sections establishes an electrically conductive connection with the carrier and at least one other of the at least two different connection sections establishes an electrically conductive connection with the electronic component.

According to still another exemplary embodiment, a method of manufacturing a substrate clip for connecting a carrier with an electronic component of a package is provided, wherein the method comprises providing an electrically insulating and thermally conductive sheet, and forming a patterned electrically conductive structure on a main surface of the electrically insulating and thermally conductive sheet so that the patterned electrically conductive structure has at least two different connection sections having different thicknesses.

According to an exemplary embodiment, a substrate adapted as a clip may be provided. Such a substrate clip may be configured for connecting a carrier with an electronic component in a package in an efficient way and with the possibility to provide extended functionality. Such a substrate clip may have an electrically insulating and thermally conductive sheet, such as a ceramic plate, providing a dielectric function with the possibility to contribute to the removal of heat created by the electronic component during operation of the package. A patterned electrically conductive structure may be formed on one side of said sheet and may be provided with two or more connection sections having different thicknesses. Such a multiple-height level electrically conductive structure on an electrically insulating and thermally conductive sheet may provide a clip functionality by connecting different connection sections with different package constituents, such as carrier and electronic component. This may allow to electrically couple the carrier and the electronic component in a compact and highly efficient way without adding noteworthy complexity to the manufacturing process and with the possibility to provide additional electrical decoupling and thermal coupling functionality to the clip and to the package as a whole. Descriptively speaking, a carrier substrate may be reconfigured with multiple connection sections of different thicknesses on the same main surface of a dielectric and thermally conductive sheet so as to be additionally functional as a clip for establishing an electric connection between constituents at different height levels while simultaneously providing electric current separation and heat dissipation functionality.

In the following, further exemplary embodiments of the substrate clip, the package and the method will be explained.

In the context of the present application, the term “substrate clip” may particularly denote a hybrid of an electrically conductive clip, enabling electric connectivity at two or more different height levels, with a substrate, providing electric insulating and thermally conductive functionality by a correspondingly configured plate. With a common insulating substrate, it may be advantageous to, on one main surface of the substrate, provide more than one patterned electrically conductive structure. For example, a first electrically conductive structure may be used to connect a drain pad of the electronic component to a drain lead of the carrier, and a second electrically conductive structure may be used to connect a source pad of the electronic component to a source lead of the carrier, and both the first and second structures may be made on one main surface of the substrate. During manufacturing, it may be advantageous to use one single pick and place process to place the substrate clip, instead of traditional two pick and place processes for a drain clip and a source clip separately.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and optionally an electric connection function. A carrier may comprise or consist of a single part, multiple parts joined via encapsulation or other package components, or a subassembly of carriers. When the carrier forms part of a leadframe structure, it may be or may comprise a die pad, and optionally also one or more lead structures. For instance, a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. At least part of the carrier may be encapsulated by an encapsulant, together with the electronic component. The carrier can be a leadframe or a substrate or a laminate. It may or may not be a metal leadframe.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “package” may particularly denote an electronic device which may comprise, in addition to at least one substrate clip, one or more electronic components mounted on a (in particular partially or entirely electrically conductive) carrier. Said constituents of the package may be optionally encapsulated at least partially by an encapsulant. Optionally, one or more electrically conductive connection elements (such as metallic pillars, bumps, bond wires and/or clips) may be implemented in a package, for instance for electrically coupling and/or mechanically supporting the electronic component.

In the context of the present application, the term “electrically insulating and thermally conductive sheet” may particularly denote a for instance plate-like physical body made of a material with electrically non-conductive and thermally conductive properties. This sheet may be made of an electrically insulator. Said electric insulator may be thermally conductive, for instance may have a thermal conductivity of at least 3 W/mK, preferably of at least 5 W/mK, and more preferably of at least at least 10 W/mK or of at least at least 20 W/mK. An appropriate material for the sheet is a ceramic material, for instance aluminum oxide, boron nitride, silicon nitride, etc. The sheet can be planar or flat. However, a sheet may also have two or more different thicknesses, in particular for a middle ceramic layer.

In the context of the present application, the term “patterned electrically conductive structure” may particularly denote a structure, in particular made of a metallic material such as copper or aluminum, having a surface profile on its exposed side facing away from the sheet. At the other side of the electrically conductive structure facing the sheet, the electrically conductive structure may be planar or flat. The electrically conductive structure may be equipped with at least two exposed connection surfaces capable of connecting constituents of a package, such as a carrier and/or an electronic component, which may be located at different height levels.

In the context of the present application, the term “connection sections having different thicknesses” may particularly denote different portions of a patterned electrically conductive structure being configured for establishing an electric connection with other constituents and being made of electrically conductive material having different thicknesses. Said different thicknesses may be provided in a direction transverse or perpendicular to a connection surface between the patterned electrically conductive structure and the sheet. Preferably but not necessarily, such a connection surface may be planar. The different connection sections may be integrally formed (for instance may be a continuous or connected electrically conductive physical structure) or may be separate from each other (for instance may be electrically decoupled electrically conductive islands).

In the context of the present application, the term “main surface” of a body may particularly denote the largest body surface of one of the largest body surfaces. For instance, a body (such as a sheet or part thereof) may be plate-shaped.

For example, different embodiments relate to a single clip single die interconnect (for instance source to drain), for instance using an architecture as shown in FIG. 1 or FIG. 4. In another embodiment, it may be possible to use a single clip with multiple die interconnects (for instance a source to a drain of the same electronic component, a source to a drain of a further electronic component, or a source of a first component to a drain of a second component, or vice versa), for instance using an architecture shown in FIG. 6 or FIG. 7. In still another embodiment, it may be possible to use a dual clip with single die interconnect, for instance using an architecture shown in FIG. 3.

In an embodiment, at least one of the at least two different connection sections comprises a metal post. Such a metal post, for instance a copper pillar, may be connected for instance to a metallic layer structure for selectively extending the vertical extension of the patterned electrically conductive structure. Such a post may extend perpendicular to a main surface of the sheet. For instance, connection of the post may be accomplished by soldering, sintering or electrically conductive glue.

In an embodiment, the at least two different connection sections comprise a first metal post and a second metal post having different vertical extensions. The first metal post and the second metal post may extend in parallel to each other. Attaching metal posts of different vertical extensions may allow to further refine the surface profile of the patterned electrically conductive structure for supporting an even larger number of different connection levels or heights.

In an embodiment, the at least two different connection sections comprise a first metallic sheet portion and a second metallic sheet portion having different vertical extensions. The metallic sheet portions may have main surfaces arranged on main surface portions of the electrically insulating and thermally conductive sheet. They may extend in their thickness direction perpendicular to said sheet up to different vertical levels. For instance, such an embodiment is shown in FIG. 4. With a configuration of mutually connected or unconnected flat metallic sheet portions, the connection of electronic constituents with a multi-level substrate clip may be made possible with low effort and in a compact and stable way.

In an embodiment, at least one of the at least two different connection sections comprises a plating structure. Said plating structure may be arranged selectively at an interface area with a carrier or with an electronic component. For example, such a plating structure may be formed selectively at an interface with another medium. For instance, the plating structure may be formed on the surface of the metal posts, more specifically on a flange face of said metal posts (see for example FIG. 15). On other parts of the connection sections, such a plating structure (for instance a plating layer) may be optional or may be omitted, in particular when such parts do not touch connected members such as a die or a lead or a leadframe. In particular, the plating structure may be formed only on the final interface to another medium (for instance due to compatibility to front side metallization, die pad surface, etc.). For example, a plating structure may be configured to enable or enhance solderability.

In an embodiment, different ones of the at least two different connection sections are electrically decoupled from each other. For example, this scenario of “decoupling” can be used for two separated patterned connection sections. For instance, one connection section may be part of a drain clip region and another connection section may be part of a source clip region. However, the scenario of “decoupling” can also be implemented for other use cases, for example to establish a connection of one connection section with a first die and a connection of another connection section with a second die.

In an embodiment, different ones of the at least two different connection sections are electrically coupled with each other. The scenario of “coupling” can be used for example for one connection section connecting a die and another connection section connecting a lead or lead post to be connected with said die.

In an embodiment, the electrically insulating and thermally conductive sheet is flat with homogeneous thickness. For example, a ceramic plate of constant thickness may be used for the sheet. This may allow to manufacture the substrate clip with very low effort.

In an embodiment, the electrically insulating and thermally conductive sheet comprises or consists of a ceramic. Ceramic materials may be reliable electrically insulators, while simultaneously providing high thermal conductivity. For example in an AMB-type substrate clip, the ceramic may be silicon nitride, whereas in a DCB-type substrate clip, the ceramic may be aluminum oxide. Many other ceramics are possible, for instance aluminum nitride or boron nitride.

In an embodiment, the substrate clip comprises a further electrically conductive structure, in particular made of solderable material, on an opposing other main surface of the electrically insulating and thermally conductive sheet. When also the main surface of the electrically insulating and thermally conductive sheet opposing the package-internal patterned electrically conductive structure with connection sections is covered with a metallic layer, solderability of this package-external surface may be enabled or enhanced. For instance, this may allow to connect a heat sink to said further electrically conductive structure for further improving thermal performance of the package.

In an embodiment, the further electrically conductive structure is a continuous layer, in particular of homogeneous thickness. This may simplify the manufacturing process of the substrate clip. For instance, it may be sufficient to simply deposit metallic material or to attach a metal foil.

In an embodiment, the substrate clip is configured as one of a Direct Copper Bonding (DCB)-type substrate, a Direct Aluminum Bonding (DAB)-type substrate, and an Active Metal Brazing (AMB)-type substrate. However, other types of substrates may also be used as a basis for forming a substrate clip, for instance an Insulated Metal Substrate (IMS).

In an embodiment, the package comprises at least one further substrate clip having the above mentioned features. For instance, such an embodiment is shown in FIG. 3. For example, a plurality of substrate clips may be arranged side-by-side and/or vertically stacked in a package. The design of different substrate clips may be the same or different. The provision of at least two substrate clips may further refine the functionality of establishing sophisticated electrically conductive paths and electric connectivity in a package, in particular in a package comprising a plurality of electronic components (such as semiconductor chips). However, it may also be possible to electrically connect a single electronic chip by two or more substrate clips.

In an embodiment, the substrate clip connects at least two different sections of the carrier and/or connects at least two electronic components. In particular, it may be possible to interconnect a plurality of electronic components by a single substrate clip only. For instance, such embodiments are shown in FIGS. 6-9. The functionality of the substrate clip providing electric connectivity at plural vertical levels may be advantageous in this context, for instance when connecting electronic components with different thicknesses and/or arranged at different vertical levels.

In an embodiment, the carrier comprises a component assembly section on which the electronic component is mounted and comprises at least one lead section being electrically coupled with the at least one electronic component and/or with the component assembly section. In particular, the component assembly section may be connected with one of the at least two connection sections, and the at least one lead section may be connected with another one of the at least two connection sections. For example, the component assembly section may be a die pad. The lead section may be provided physically separate from the die pad or integrally connected with the die pad. The described configuration may allow to physically connect source leads, for example.

In an embodiment, the main surface of the substrate clip opposing the patterned electrically conductive structure forms part of an exterior surface of the package. Said main surface may be constituted by the electrically insulating and thermally conductive sheet and/or by a further electrically conductive structure formed on said sheet. In particular, the electrically insulating and thermally conductive sheet may be exposed at a main surface of the package. This may promote heat removal via the thermally conductive sheet, for instance a ceramic sheet. In another embodiment, said sheet may be covered on an exposed exterior side with a further electrically conductive structure, such as a continuous metallic layer. Also such a further electrically conductive structure or a heat sink attached to such a further electrically conductive structure may further promote heat dissipation out of the package.

In an embodiment, a main surface of the carrier forms part of an exterior surface of the package. In particular, a main surface of a component assembly section, such as a die pad, of the carrier, may form part of an exposed main surface of the package. This may promote heat dissipation from the electronic component in an interior of the package through the highly thermally conductive carrier towards an environment.

In particular in an embodiment, in which one main surface of the package is formed at least partially by a main surface of the carrier and the opposing other main surface of the package is formed at least partially by the exposed substrate clip, double-sided cooling may be achieved via the exposed carrier and via the exposed substrate clip. This may lead to an excellent thermal performance of the package.

In an embodiment, the package comprises an encapsulant, for example a mold compound, encapsulating part of the carrier, at least part of the substrate clip, and at least part of the electronic component, wherein in particular the substrate clip protrudes out of the encapsulant (which may provide a mold lock feature) or is coplanar with the encapsulant. In the context of the present application, the term “encapsulant” may particularly denote a material, structure or member surrounding or intended for surrounding at least part of an electronic component and at least part of a carrier of a package. In this context, an encapsulant may provide mechanical protection and electrical insulation, and optionally a contribution to heat removal during operation. In particular, said encapsulant may be electrically insulating, for instance a mold compound. A mold compound may comprise a matrix of flowable and hardenable material, in particular a resin, optionally one or more additives, and optionally filler particles embedded therein. As an alternative to a mold compound (for example on the basis of epoxy resin), the encapsulant may also be a potting compound (for instance on the basis of an epoxy).

In an embodiment, the electronic component is arranged in a flip chip configuration and has an active region at its front side which is connected with the carrier. An active region may be a portion of a semiconductor body in which at least one monolithically integrated circuit element is formed. Said active region may be arranged to face the carrier. In particular, such an electronic component arranged in a flip chip configuration may be a vertical die (like a MOSFET, an IGBT, a vertical GaN die, etc.). The electronic component's front surface or patterned surface may be attached to the carrier. Also in such a flip chip configuration, connectivity inside of the package may be promoted or established by a substrate clip as described herein.

In an embodiment, the electronic component and a further electronic component are connected in a half bridge configuration. In the context of the present application, the term “half bridge” may particularly denote a circuit composed of an upper transistor switch (“high-side”) and a lower transistor switch (“low-side”). For instance, the transistors may be MOSFETs, i.e. metal oxide semiconductor field effect transistors. The transistors may be connected in a cascode arrangement. The two transistor switches may be turned on and off complementary to each other (in particular with a non-overlapping dead-time) by applying corresponding voltage waveforms at the control terminals. A desired result may be an idealized DC-DC conversion scenario, where a square-wave mid voltage level switches between a first electric potential (such as a DC (direct current) bus voltage) and a second electric potential (such as ground). However, other shapes of an output signal may be possible which do not have a square-wave characteristic. The two transistors may be interconnected with a mutual connection of their connection terminals so that a two-transistor based switch with implemented diode characteristic may be obtained. The mentioned half bridge configuration may be used as such or alone or may be combined with one or more further half bridges (or other electric circuits) to realize a more complex electric function. For instance, two such half bridges may form a full bridge.

In an embodiment, the different connection sections have at least three different thicknesses. In order to establish even more sophisticated electronic connections inside of the package, the different connection sections may even have four, five or even more different thicknesses.

In an embodiment, the different connection sections have a first thickness connecting the electronic component, a second thickness connecting a further electronic component, and a third thickness connecting the carrier. Such an embodiment is shown, for instance, in FIG. 7 to FIG. 9.

In an embodiment, the package comprises at least one further electronic component mounted on the carrier. For instance, the package may be a two-die package or more generally a multiple-die package. The dies may share a common substrate clip which may have a common intermediate sheet (which may be made of ceramic). However, different electronic components may be also connected by different substrate clips.

In an embodiment, the electronic component comprises at least one terminal facing the substrate clip. For example, also a plurality of terminals or even all terminals of the electronic component may face the substrate clip. For instance, this may be the case when the electronic component is a lateral electronic component. A corresponding embodiment is shown for instance in FIG. 7 to FIG. 9.

In an embodiment, the electronic component has at least one terminal on each of both opposing main surfaces thereof. For example, this may be the case when the electronic component is a vertical electronic component. For instance, such a vertical electronic component may be a transistor chip having a source terminal and a gate terminal on one main surface and a drain terminal on the opposing main surface of the electronic component.

In an embodiment, the method comprises forming the patterned electrically conductive structure with the at least two different connection sections having different thicknesses by treating an initial electrically conductive structure using a first mask to thereby form an intermediate electrically conductive structure having a homogeneous thickness, and thereafter treating the intermediate electrically conductive structure using a second mask to thereby obtain the patterned electrically conductive structure with the at least two different connection sections having different thicknesses. Such an embodiment is shown for instance in FIG. 10 to FIG. 13. For example, said “treating” may comprise “etching”. However, it may also be possible, in terms of said treating, to deposit an alloy or a metal to create different heights. For instance, this may be accomplished by copper plating. Growing a metal post on an insulative substrate may be possible as well. In one embodiment, a DCB or an AMB may be provided first, then an etching process may be carried out to remove a part of the copper to form metal posts. Multiple masking and multiple etching can form different height levels. In another embodiment, it may be possible to provide an insulative sheet or substrate. Then, a masking and metal depositing process may be executed to form metal posts. Multiple masking and multiple depositing processes may allow to form different heights.

In an embodiment, the method comprises forming the patterned electrically conductive structure with the at least two different connection sections having different thicknesses by providing an initial electrically conductive structure having a homogeneous thickness, and thereafter attaching at least one post to the initial electrically conductive structure to thereby obtain the patterned electrically conductive structure with the at least two different connection sections having different thicknesses. In such another alternative solution to make a two (or more than two) heights substrate clip, the heights are not defined by etching, but by attaching, soldering and/or welding another metal post. Attaching may be done for example by soldering, welding, brazing, deposition and/or attaching with additional paste or another medium. Different posts of different thicknesses may be attached for further increasing the number of height levels supported by the substrate clip.

In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user convenient.

In an embodiment, the electronic component is a semiconductor power chip. Thus, the semiconductor component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the package comprises a plurality of electronic components, in particular semiconductor components, encapsulated by the package encapsulant. Thus, the package may comprise one or more semiconductor components (for instance at least one passive component, such as a capacitor, and at least one active component).

As substrate or wafer forming the basis of the electronic component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package with a substrate clip according to an exemplary embodiment.

FIG. 2 illustrates a cross-sectional view of a package with a substrate clip according to another exemplary embodiment.

FIG. 3 illustrates a cross-sectional view of a package with two substrate clips according to another exemplary embodiment.

FIG. 4 illustrates a cross-sectional view of a package with a substrate clip according to another exemplary embodiment.

FIG. 5 illustrates a three-dimensional view of a part of a substrate clip before and after creating different connection sections at different height levels according to an exemplary embodiment.

FIG. 6 illustrates a cross-sectional view of a package with a substrate clip and two electronic components according to another exemplary embodiment.

FIG. 7 illustrates a cross-sectional view of a package with a substrate clip and two electronic components according to another exemplary embodiment.

FIG. 8 illustrates a plan view of the package according to FIG. 7.

FIG. 9 illustrates a cross-sectional view of a package with a substrate clip and two electronic components according to another exemplary embodiment.

FIG. 10 to FIG. 13 shows cross-sectional views of structures obtained during carrying out a method of manufacturing a substrate clip for a package according to an exemplary embodiment.

FIG. 14 and FIG. 15 shows cross-sectional views of structures obtained during carrying out a method of manufacturing a substrate clip for a package according to another exemplary embodiment.

FIG. 16 illustrates a plan view and a cross-sectional view of a conventionally wired half bridge package with electronic components in gallium nitride technology.

FIG. 17 illustrates a plan view and a cross-sectional view of a half bridge package with a substrate clip and electronic components in gallium nitride technology according to an exemplary embodiment.

### DETAILED DESCRIPTION

The illustrations in the drawings are schematic and not to scale.

Before exemplary embodiments will be described in more detail referring to the figures, some general considerations will be summarized based on which exemplary embodiments have been developed.

Conventionally, substrates such as a Direct Copper Bonding (DCB) substrate may be used as chip carriers. Independently from this, metallic clips may be three-dimensionally curved metallic plate bodies for interconnecting constituents of a package.

In particular when using wide bandgap semiconductor components in a package, clip interconnect may support higher complexity package designs. At the same time, industry is targeting for higher current rating, minimizing inductance, lowering Rdson, as well as enabling better thermal performance. While clips may add material cost to a package, clips may simultaneously reduce the manufacturing effort compared with wire bonding. For instance, clips may be advantageous in gallium nitride chip packages.

However, there may still be a need for packages and related constituents providing enhanced functionality while simultaneously allowing a compact design and low manufacturing effort.

According to an exemplary embodiment, a substrate with an electrically conductive surface topography on one main surface may be provided for offering a clip functionality in addition to a substrate functionality by a single integral electronic member or package constituent. Such a substrate clip, when implemented in a package, may be capable of electrically coupling a carrier (such as a leadframe structure) with an electronic component (for instance a semiconductor chip) while simultaneously providing electric decoupling and thermal coupling functionality in the package. The substrate clip may have an electrically insulating and thermally conductive sheet, for example made of a ceramic material and for instance embodied as a flat or planar structure. Such a sheet may electrically decouple a connected constituent, such as an electronic component, from an exterior of the package. Simultaneously, such sheets may provide a contribution to the dissipation of heat created by a for instance encapsulated electronic component of a package during use. Advantageously, a patterned electrically conductive structure on one main surface on said sheet may have plural mutually connected or disconnected connection sections being connectable at different height levels as a consequence of different thicknesses of said connection sections. Hence, a substrate clip with simple construction and nevertheless extended functionality may be provided which can be considered as a hybrid of a carrier substrate and a metallic clip. Such a substrate clip may make it possible to establish in a package an electric connection between a carrier and an electronic component with low manufacturing effort and short connection paths while simultaneously contributing to an electric insulation task and a thermal coupling task within the package. This may be made possible by equipping a dielectric and thermally conductive plate with a metallic pattern having a multiple height levels surface profile on one side of the plate.

In an embodiment, the substrate may be embodied as a DCB (Direct Copper Bonding) clip or an AMB (Active Metal Brazing) clip. Thus, the substrate clip may be formed based on a DCB design or an AMB design, however with an electrically conductive structure on one main surface having a multiple-thickness surface profile for supporting electric connection at two or more different height levels even when mounted horizontally. More generally, a substrate clip according to an exemplary embodiment may be denoted as a clip that is in the form of substrate. A substrate clip according to an exemplary embodiment may be a clip able to stack on top of a die pad or a lead post and having simultaneously an electrically insulating and thermally conductive sheet section.

For example, a substrate clip may be formed with a clip design enabling a separation of source and drain of a field-effect transistor-type electronic component with thermally conductive but electrically insulating material. In an embodiment, it may be possible that the substrate clip can couple with an electronic component in a flip chip configuration.

For example, a substrate clip may be configured so as to be connectable for re-using existing front side metallization and/or back side metallization. It may also be possible to use a substrate clip according to an exemplary embodiment with an existing die attach method, such as soft soldering. Additionally or alternatively, it may be possible to use a substrate clip according to an exemplary embodiment with an existing clip attach method, for example using solder paste (which may be dispensed).

Advantageously, a substrate clip according to an exemplary embodiment may improve electrical performance and may reduce a form factor for greater package reliability, better thermal transfer, and/or ultra-fast switching. Furthermore, a substrate clip according to an exemplary embodiment may enable to design a package with dual sided cooling thanks to the high thermal conductivity of the (in particular ceramic) sheet.

In particular, a package with dual side cooling may be formed using a substrate clip according to an exemplary embodiment by exposing the substrate clip's ceramic surface and/or an electrically conductive structure formed thereon. Embodiments may allow to establish a single pass clip attach. Advantageously, an embodiment may make it possible to increase the DCB clip thickness to achieve better thermal performance. In an embodiment, a substrate clip may be arranged on top of one or more electronic components (such as semiconductor dies), acting as interconnect.

For instance, a substrate clip according to an exemplary embodiment may be formed by pre-plating a copper surface of a DCB- or AMB-type substrate or ceramic sheet thereof. In particular, such a substrate clip may be pre-plated for example with NiNiP/Ag to enable different type of interconnect. A connection surface of the substrate clip may be pre-plated (for instance with Ag/NiNiP surface) for providing a contact point to the electronic component and/or the carrier. Furthermore, it may be possible to enhance the substrate clip interface for better adhesion to an electronic component (such as a chip) or a carrier (for instance a leadframe structure).

In particular, a substrate clip according to an exemplary embodiment may be used with one or more of the following configurations: In an embodiment, the electronic component of a package coupled by a substrate clip according to an exemplary embodiment may be a wide band gap die and/or a lateral die. For instance, an electronic component of the package connected with a substrate clip according to an exemplary embodiment may be a semiconductor chip manufactured in GaN technology or SiC technology. In case of down bond interconnects, a material interface may be present.

In one embodiment, a single substrate clip may be provided in a package and may have two or more different height levels. For instance, a patterned electrically conductive structure of a substrate clip may be made based on a copper layer. The substrate clip may be formed on the basis of a DCB. In particular, the top side of the substrate clip may be made of a ceramic, and its bottom side may be a patterned metal to have two or more different heights for contacting two or more targets at different planes or height levels.

In another embodiment, a substrate clip may have a common ceramic sheet as support for two clip sections in form of different patterned metal sections, wherein the clip sections may be made by etching a copper layer of a DCB. The vertical part of the metallic clip assembly may be equipped with two, three or more different heights.

In embodiments, it may be possible to interlock the substrate clip to a lead post, for instance by a stepped or coined design. For instance, it may be possible that the substrate clip is in direct contact to a lead post. For instance, no conductive material needs to be present between source terminal and drain terminal of a field-effect transistor-type electronic component.

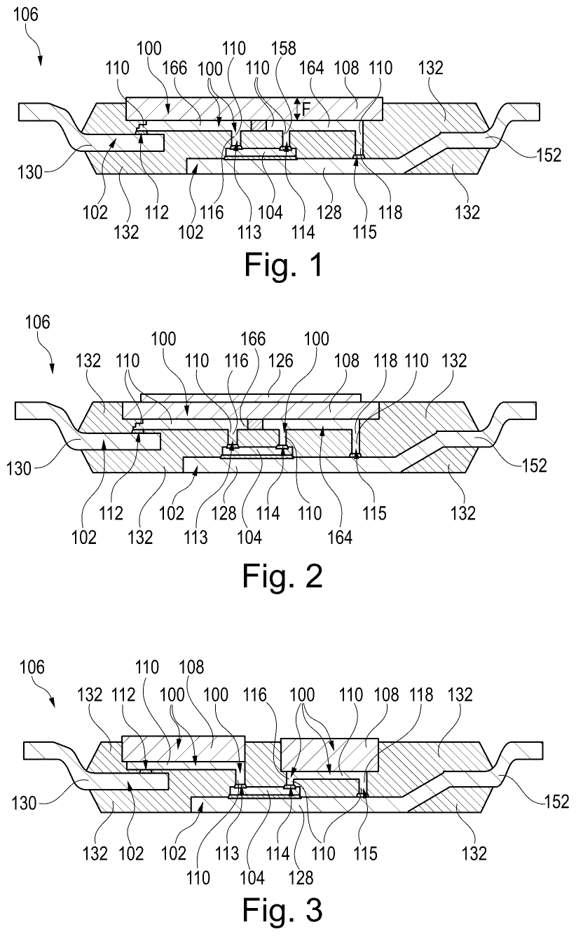

FIG. 1 illustrates a cross-sectional view of a package 106 with a substrate clip 100 according to an exemplary embodiment.

The illustrated package 106 comprises a carrier 102, which is here embodied as a leadframe structure. Thus, the carrier 102 may be a patterned and bent metal plate, for instance made of copper or aluminum. As shown, the carrier 102 comprises a component assembly section 128, such as a die pad with integrally connected lead section 152, and comprises a further separate lead section 130.

Furthermore, package 106 comprises an electronic component 104, such as a semiconductor chip, which is mounted on the carrier 102. More specifically, the electronic component 104 is mounted on the die pad-type component assembly section 128 of the carrier 102. For example, electronic component 104 may be a field-effect transistor-type semiconductor chip. For instance, the electronic component 104 may be soldered or sintered onto the component assembly section 128.

Advantageously, package 106 comprises a substrate clip 100 which is configured as a hybrid of a substrate and a clip. The substrate clip 100 is connected in the framework of the package 106 for electrically and mechanically connecting the carrier 102 with the electronic component 104, as described below in further detail. Although shown as a constituent of package 106, the substrate clip 100 may be a separate and integral electronic member before assembly with the other constituents, such as carrier 102 and electronic component 104. The substrate clip 100 is composed of an electrically insulating and thermally conductive sheet 108 and a patterned electrically conductive structure 110 and may be provided as a pre-formed individual body which may be used, in particular, as a constituent for package 106.

As shown, the substrate clip 100 comprises electrically insulating and thermally conductive sheet 108. The electrically insulating and thermally conductive sheet 108 may be a planar body, for instance a flat plate with parallel main surfaces. More specifically, the electrically insulating and thermally conductive sheet 108 may have a homogeneous thickness F. The electrically insulating and thermally conductive sheet 108 may be made of a ceramic material, for instance may be made of silicon nitride or aluminum oxide. Consequently, sheet 108 combines reliable dielectric properties with high thermal conductivity.

Furthermore, the substrate clip 100 comprises patterned electrically conductive structure 110 on one main surface (in the shown embodiment the bottom main surface) of the electrically insulating and thermally conductive sheet 108. According to FIG. 1, the opposing main surface (in the shown embodiment the top main surface) of the electrically insulating and thermally conductive sheet 108 is free of a metallic coverage and is thus defined by a ceramic surface. The bottom-sided patterned electrically conductive structure 110 may for instance comprise copper and/or aluminum. Advantageously, the surface of the patterned electrically conductive structure 110 facing the electronic component 104 and the carrier 102 has a pronounced surface profile or topography and thereby provides a plurality of different connection sections 112-115 having different vertical thicknesses and extending up to different vertical height levels. More specifically, a first connection section 112 may be formed at a bottom surface of a first planar layer section 166 of the electrically conductive structure 110 and is connected, in the shown embodiment, with the lead section 130 of the carrier 102. A second connection section 113 may be formed by a metal post 116 extending downwardly from the first planar layer section 166 and is connected, in the shown embodiment, with a first electric terminal at a top main surface of the electronic component 104. A third connection section 114 may be formed by a further metal post 158 extending downwardly from a second planar layer section 164 of the electrically conductive structure 110 and is connected with a second electric terminal at the top main surface of the electronic component 104. A fourth connection section 115 may be formed by yet another metal post 118 extending downwardly from the second planar layer section 164 and is connected with the component assembly section 128 of the carrier 102. In the illustrated embodiment, connection sections 113, 114 extend downwardly up to the same vertical level due to the same vertical thicknesses of metal posts 116, 158. Since metal post 118 has a larger vertical thickness than metal posts 116, 158, connection section 115 extends further downwardly than connection sections 113, 114. Furthermore, connection sections 113, 114 extend further downwardly than connection section 112 (the latter being formed without post). Thus, the different connection sections 112-115 have three different thicknesses according to FIG. 1 and support electric connectivity at three different vertical levels in the horizontal orientation of substrate clip 100 according to FIG. 1. Hence, connection sections 112-115 contribute to a surface profile of the bottom surface of the patterned electrically conductive structure 110. Consequently, connection sections 112-115 of the substrate clip 100 enable the connection with electronic members 130, 104, 128 located at different vertical levels of the package 106. Before connecting substrate clip 100 with the other constituents of the package 100, metal posts 116, 158, 118 (for instance copper pillars) may already be integrally connected with the electrically separated planar layer sections 166, 164 so as to form part of the substrate clip 100 and its patterned electrically conductive structure 110 already before assembly of the package 106. Only during package assembly, the metal posts 116, 158, 118 are connected with carrier 102 and electronic component 104. Hence, the metal posts 116, 158, 118 initially form an integral part of the clip substrate 100 rather than of the electronic component 104 or of the carrier 102. In other words, the metal posts 116, 158, 118 are clip substrate-sided.

As mentioned, the multiple-height connection sections 112-115 may establish an electrically conductive connection with electric terminals of the electronic component 104 and with the component assembly section 128 and the lead section 130 of the carrier 102. For instance, the electric connection between the respective connection section 112-115 and the connected electronic constituents or members (in particular carrier 102 or electronic component 104) may be established by an electrically conductive connection medium, such as a solder, a sinter paste or electrically conductive glue.

Referring to the above description, the electronic component 104 comprises two terminals facing the substrate clip 100 and facing away from component assembly section 128. Moreover, the electronic component 104 has one further terminal facing the component assembly section 128 and facing away from the substrate clip 100. Hence, the electronic component 104 according to FIG. 1 has terminals on both opposing main surfaces thereof and may for instance be a vertical electronic component. In the shown embodiment, the electronic component 104 may be a field-effect transistor chip with a drain terminal on the bottom side and a source terminal as well as a gate terminal on the top side.

Any of the horizontal surface portions of the connection sections 112-115 may be selectively covered or equipped with a plating structure (see reference sign 120 in FIG. 15) at an interface area with the respectively connected electronic member or constituent, in the shown embodiment at an interface area with the carrier 102 or with the electronic component 104, respectively. Said plating structure may enable, enhance or promote the connection in between. For example, such a plating structure may be embodied as an Ag/NiNiP layer.

A part of the different connection sections 112-115 may be electrically decoupled from each other. In the shown embodiment, connection sections 112, 113 may be electrically decoupled from connection sections 114, 115. It is also possible that a part of the different connection sections 112-115 are electrically coupled with each other. In the shown embodiment, connection sections 112, 113 are electrically coupled with each other, and connection sections 114, 115 are also electrically coupled with each other.

For example, the substrate clip 100 may be configured as a Direct Copper Bonding-type substrate, a Direct Aluminum Bonding-type substrate, or an Active Metal Brazing-type substrate, however with a profiled metallic surface enabling connection of one or more electronic constituents at more than one vertical level thanks to differently thick connection sections 112-115 of the substrate clip 100.

Again referring to FIG. 1, package 106 comprises an encapsulant 132, which is here embodied as a mold compound. The encapsulant 132 may comprise, for example, a resin material, in particular an epoxy resin material. The material of the encapsulant 132 can, in particular, comprise a resin like an epoxy resin material filled with particles like, for example, SiO or other ceramic particles, for examples, Al₂O₃, BN, AlN, Si₃N₄, diamond. The encapsulant 132 encapsulates part of the carrier 102, part of the substrate clip 100, and the entire electronic component 104.

As shown in FIG. 1, the upper main surface of the substrate clip 100 protrudes out of the encapsulant 132. However, the substrate clip 100 may be alternatively coplanar with the encapsulant 132. Advantageously, the upper main surface of the substrate clip 100 opposing the patterned electrically conductive structure 110 is exposed relatively to the encapsulant 132 and therefore forms part of an exterior surface of the package 106. More specifically, the upper main surface of the electrically insulating and thermally conductive sheet 108 forms part of the exterior surface of the package 106. At the bottom side of the package 106, a lower main surface of the metallic component assembly section 128 of the carrier 102 forms part of an exterior surface of the package 106. Thus, a significant part of the bottom main surface of the package 106 is formed by the metallic material of the carrier 102 and a significant part of the top main surface of the package 106 is formed by the ceramic material of the substrate clip 100. This configuration leads to a double-sided cooling architecture of package 106. Hence, heat generated by the encapsulated electronic component 104 during operation of the package 106 may be efficiently removed towards a bottom side by the exposed highly thermally conductive metallic material of the carrier 102 and towards a top side by the exposed highly thermally conductive ceramic material of the substrate clip 100. Advantageously this may allow to provide a package 106 with excellent thermal performance.

The embodiment of FIG. 1 shows a package 106 which has a single die in form of the electronic component 104 and a single substrate clip 100. More specifically, a pre-designed substrate clip 100 may be provided in the form of an AMB-like or a DCB-like body with profiled metallic connection pattern. In this embodiment, a direct clip-to-post contact may be established. No conductive connection is established between source and drain in the shown embodiment. Connection areas of the patterned electrically conductive structure 110 may be selectively pre-plated, for instance with Ag/NiNiP surface for providing a respective contact point to the electronic component 104 and the carrier 102. Bare copper may also be covered. No glue or solder may be required on a lead post area. It may be sufficient to provide one time glue dispensed on a die area. With the shown architecture, it may be possible to simplify a clip process for reducing the entire manufacturing effort. A consistent clip height may provide a good planarity which is highly appropriate for diffusion soldering. Also a die on clip configuration may be made possible. Based on the architecture shown in FIG. 1, it may also be possible to provide a multi-chip configuration. This architecture may also be combined with wire bonding.

FIG. 2 illustrates a cross-sectional view of a package 106 with a substrate clip 100 according to another exemplary embodiment.

The embodiment of FIG. 2 differs from the embodiment of FIG. 1 in particular in that, according to FIG. 2, the clip substrate 100 comprises a further electrically conductive structure 126 on an opposing other main surface of the electrically insulating and thermally conductive sheet 108 as compared to its other main surface carrying the patterned electrically conductive structure 110. As shown, the further electrically conductive structure 126 can be a continuous metal layer. The further electrically conductive structure 126 opposes the patterned electrically conductive structure 110. Advantageously, the further electrically conductive structure 126 may be made of solderable material, such as copper. Consequently, the further electrically conductive structure 126 forming part of an exposed surface of the package 106 may be solder-connected with a heat sink (not shown). For instance, such a heat sink may comprise a highly thermally conductive plate connected with a plurality of cooling fins. When connected on the further electrically conductive structure 126, the heat sink may further improve the thermal performance of the package 106 by providing an additional contribution for dissipation of heat away from the package 106. For instance, such a heat sink may be made of a metallic or a ceramic material.

Although not shown, it may be possible in other embodiments for other electronic applications that the patterned electrically conductive structure 110 of FIG. 2 comprises a single planar layer section, rather than two separated planar layer sections 164, 166 as in FIG. 2. In such an embodiment, all connection sections 112-115 are electrically coupled with each other.

FIG. 3 illustrates a cross-sectional view of a package 106 with two substrate clips 100 of different vertical thickness according to another exemplary embodiment. Alternatively, the package configuration of FIG. 3 may also cover a single die package and a single clip.

The embodiment of FIG. 3 differs from the embodiment of FIG. 1 in particular in that, according to FIG. 3, the package 106 has two separate substrate clips 100 both being partially encapsulated by the same encapsulant 132. According to FIG. 3, the substrate clips 100 are arranged side-by-side. The substrate clips 100 are arranged at different vertical levels according to FIG. 3. Furthermore, the substrate clips 100 may have electrically insulating and thermally conductive sheets 108 of different thicknesses. Providing two or more different DCB- and/or AMB-type substrate clips 100 may further increase the flexibility of design. In particular, a lower risk of tilt may be obtained due to the provision of multiple separated substrate clips 100. A consistent substrate clip height may provide good planarity for the respective substrate clip 100 which is in particular suitable for diffusion soldering. Also a good thermal conductivity may be obtained with the illustrated design. Moreover, the shown embodiment is particularly appropriate for source down designs.

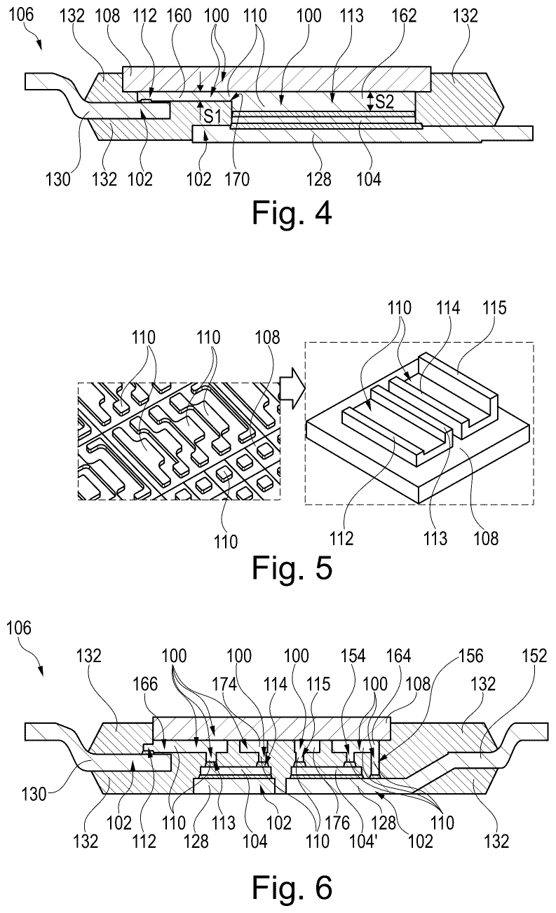

FIG. 4 illustrates a cross-sectional view of a package 106 with a substrate clip 100 according to another exemplary embodiment.

The embodiment of FIG. 4 differs from the embodiment of FIG. 1 in particular in that, according to FIG. 4, the different connection sections 112-115 providing connection areas at different height levels are provided by a patterned electrically conductive structure 110 having a first metallic sheet portion 160 with a first vertical extension s1 and integrally formed with a second metallic sheet portion 162 with a second vertical extension s2 being larger than the first vertical extension s1. The first metallic sheet portion 160 and the second metallic sheet portion 162 may be a common piece of metal. Thus, the patterned electrically conductive structure 110 according to FIG. 4 shows a stepped planar metallic configuration with a vertical step 170 between the integral metallic sheet portions 160, 162 of different thicknesses s1, s2. Advantageously, this design is particularly simple and nevertheless provides connection with a lead section 130 and an electronic component 104 at different vertical levels.

The architecture of FIG. 4 may be advantageous in particular for a vertical die, wherein the bottom of the die electrically connects the die pad-type component assembly section 128 and its connecting lead, and the top of the die electrically connects to the lead sections 130, 152 via this substrate clip 100. In this substrate clip 100, there may be one common insulative substrate or sheet 108 and metal posts of different heights.

FIG. 5 illustrates, on the left-hand side, a three-dimensional view of a part of a substrate clip 100 (or a pre-form thereof) before creating different connection sections at different height levels according to an exemplary embodiment. On the right-hand side, FIG. 5 shows a three-dimensional view of a part of a substrate clip 100 after creating different connection sections 112-115 of a patterned electrically conductive structure 110 at different height levels. For example, the different heights may be formed by multiple etching.

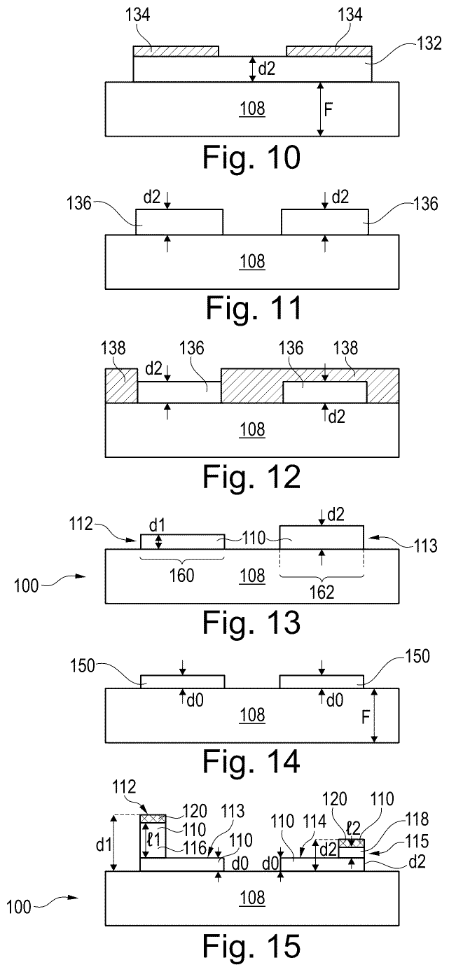

Descriptively speaking, the left-hand side of FIG. 5 illustrates that a metal layer, in particular a copper layer, may be freely patterned on an electrically insulating and thermally conductive sheet 108 for defining a patterned electrically conductive structure 110 of any desired design. Thus, the surface of a copper layer may be designed in accordance with any desired application. For imposing a vertical surface profile on the patterned electrically conductive structure 110, a subtractive process (for instance involving masking and etching), an additive process (for example involving masking and metal deposition) and/or a metal post or pillar assembly process may be executed. Examples are given in FIG. 10 to FIG. 15. An example is shown on the right-hand side of FIG. 5 where different connection sections 112-115 of patterned electrically conductive structure 110 are shown having different thicknesses. In this embodiment, any of the connection sections 112-115 may be shaped as a web or strip.

FIG. 6 illustrates a cross-sectional view of a package 106 with a substrate clip 100 and two electronic components 104, 104′ according to another exemplary embodiment. Alternatively, the package design of FIG. 6 may also cover a single die package and a single clip.

The embodiment of FIG. 6 differs from the embodiment of FIG. 1 in particular in that, according to FIG. 6, a further electronic component 104′ is mounted on the carrier 102 and is also electrically coupled by the patterned electrically conductive structure 110 of the substrate clip 100. Thus, two (or more) electronic components 104, 104′ may be assembled on the same carrier 102 and may be interconnected by a common substrate clip 100. More specifically, carrier 102 of FIG. 6 has two die pads or component assembly sections 128, 128, each for carrying a respective electronic component 104, 104′. The patterned electrically conductive structure 110 of FIG. 6 comprises four (rather than two) planar layer sections 164, 166, 174, 176, two for each electronic component 104, 104′. Five metallic posts extend from the planar layer sections 164, 166, 174, 176, partially up to the same vertical level, and partially to another vertical level for establishing electric connections with the electronic components 104, 104′ and optionally the carrier 102. For instance for leaded half-bridge package, it may be dispensable to provide one source clip connecting to the die pad. For example, a small and short clip may be provided for connecting the source pad of one die to the die pad which then further connects to the source leads. Also planar layer section 166 itself establishes an electric connection with lead section 130 of carrier 102 by connection section 112. Altogether, substrate clip 100 provides six connection sections 112-115, 154, 156.

FIG. 6 shows that a substrate clip 100 may allow to establish electric connections in a package 106 comprising multiple dies. For example, such multiple dies may be gallium nitride dies for forming a half bridge configuration. An interlock of the substrate clip 100 to lead posts may be possible, for instance with a step or coined design.

Thus, different embodiments may use a single die configuration or a dual die combination. Even more than two chips may be present in one package 106. It may also be possible to use a single die pad or multiple die pads, for example for a half bridge as well. A clip to lead post direct contact may be possible. No conductive material needs to be present between source and drain. Also in this embodiment, a pre-plating is possible, for instance by providing an Ag/NiNiP surface for a contact point to a chip. In particular, it may be possible to realize a single and a multiple die pad with multi-chip configuration.

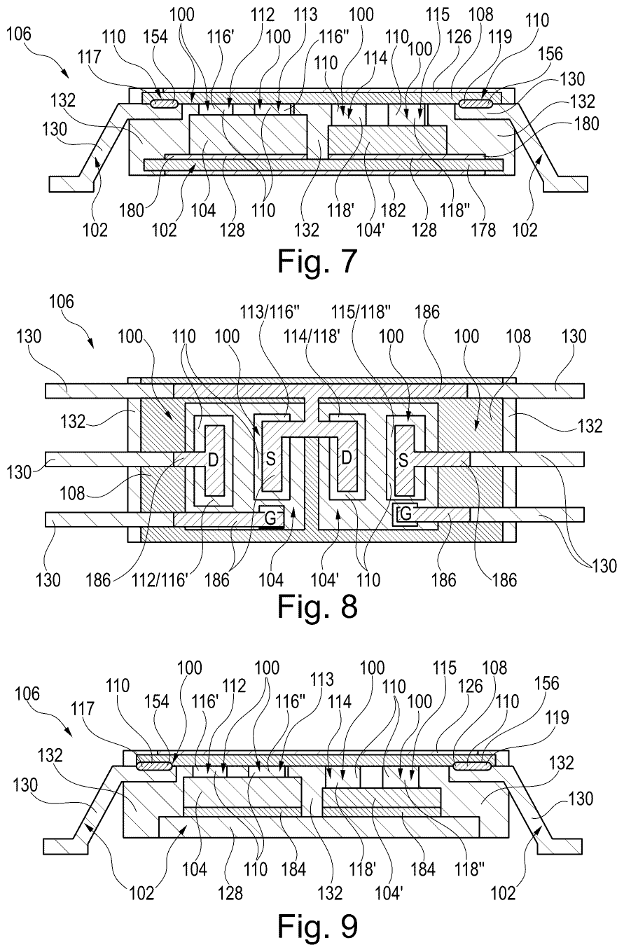

FIG. 7 illustrates a cross-sectional view of a package 106 with a substrate clip 100 and two electronic components 104, 104′ according to another exemplary embodiment. FIG. 8 illustrates a plan view of the package 106 according to FIG. 7. FIG. 9 illustrates a cross-sectional view of another package 106 with a substrate clip 100 and two electronic components 104, 104′ according to another exemplary embodiment.

In the embodiment of FIG. 7, carrier 102 comprises a substrate having a ceramic sheet 178 arranged between two opposing metal structures 180, 182 (such as copper layers). For example, said substrate may be a Direct Copper Bonding (DCB) substrate, an Active Metal Brazing (AMB) substrate, or an Insulated Metal Substrate (IMS). In the embodiment of FIG. 9, carrier 102 is embodied on the basis of one or more metallic plates or as a leadframe structure. In FIG. 9, the electronic components 104, 104′ may be mounted on a common component assembly section 128 of carrier 102 by an electrically insulating connection medium 184, such as non-conductive glue.

In the shown embodiments, the electronic components 104, 104′ may be lateral dies. Source, drain and gate pads are disposed at the upper main surface of the semiconductor die-type electronic components 104, 104′. Furthermore, each of the electronic components 104, 104′ may comprise a high electron mobility transistor (HEMT).

In both embodiments of FIG. 7 and FIG. 9, the electronic component 104 and the further electronic component 104′, having different vertical thicknesses, are connected in a half bridge configuration due to their interconnection by substrate clip 100. To accomplish this, the different connection sections 112-115, 154, 156 have a first thickness (see connection sections 112, 113) connecting the thicker electronic component 104, a second thickness (see connection sections 114, 115) connecting the thinner further electronic component 104′, and a third thickness (see connection sections 154, 156) connecting lead sections 130 of the carrier 102 at a higher height level than the electronic components 104, 104. Simply speaking, connection sections 114, 115 may have a first vertical thickness which is larger than a second vertical thickness of the connection sections 112, 113. Said second vertical thickness may be larger than a third vertical thickness of the connection sections 154, 156.

In particular, FIGS. 7-9 show a half-bridge configuration. For example, the substrate clip 100 has three (or more generally at least three) different connection heights. Posts 116′, 116″ connect to the same die or electronic component 104 which may connect the high side of the half-bridge configuration (i.e., first die). More specifically, post 116′ may connect to the drain terminal of the first die and post 116″ may connect the source terminal of the first electronic component 104. In this configuration, posts 116′ and 116″ have the same height, but they are electrically decoupled or disconnected along the bottom surface of the substrate clip 100. Posts 118′, 118″ connect to the other die or further electronic component 104′ which may correspond to the low side of the half-bridge, i.e. the second die. More specifically, post 118′ may connect to the drain terminal of the second die and post 118″ may connect the source terminal of the second electronic component 104′. Source, drain and gate connections can be seen in FIG. 8. Posts 118′, 118″ have the same height, but are electrically decoupled from each other (as described above for posts 116′, 116″). Moreover, posts 116″ and 118′ may connect with each other via the bottom metal pattern of the substrate clip 104. Hence, there are already two different heights for this substrate clip 104 due to the connection to the electronic components 104, 104′.

In case the substrate clip 100 cannot lie easily on the left leads and right leads of lead sections 130, 130 (for instance when the height of posts 116′, 116″ and 118′, 118″ do not match the height difference between the position of the left/right leads compared to the top surfaces of the first and second dies), then for the substrate clip 104, there can be a further fifth post 117 or another conductive structure and a sixth post 119 or another conductive structure, to compensate the height difference, so that the substrate clip 100 can be easily attached to the lead sections 130, 130 no matter the height difference.

As can be seen in FIG. 8, the bottom metal layer of the substrate clip 100 is patterned to form connection wiring 186.

One advantage of the illustrated exemplary embodiments can be seen in the extremely short connection paths between the electrical components 104, 104′, through which parasitic inductances of the electrical connections between contact pads of the semiconductor transistor dies and external contacts can be reduced or even minimized. These parasitic inductances may lead to a delay in the power slew rates in the main current path between source and drain. Especially with high load currents and high temporal current changes, even small parasitic inductances can lead to significant voltage drops in the electrical connections.

FIG. 10 to FIG. 13 shows cross-sectional views of structures obtained during carrying out a method of manufacturing a substrate clip 100 for a package 106 according to an exemplary embodiment.

Referring to FIG. 10, starting point of the manufacturing method may be an electrically insulating and thermally conductive sheet 108. For instance, sheet 108 may be a planar ceramic plate having a constant thickness F.

An initial electrically conductive structure 132, such as a metal layer (for instance made of copper), of constant thickness d2 may be applied on one main surface of the sheet 108. Thereafter, a first mask 134 may be formed on defined parts of the initial electrically conductive structure 132, for instance by lithography or by patterned deposition.

Referring to FIG. 11, a patterned intermediate electrically conductive structure 136 having the homogeneous thickness d2 is formed by subjecting the structure shown in FIG. 10 to etching for selectively removing exposed metallic material of the initial electrically conductive structure 132. The etching process may be selected so that the first mask 134 protects metallic material underneath from being removed by etching. After this metal etching process, the first mask 134 may be removed, for instance by stripping. This treatment leads to the structure shown in FIG. 11 with a patterned intermediate electrically conductive structure 136 of continuous thickness d2.

Referring to FIG. 12, part of the intermediate electrically conductive structure 136 is then covered by a patterned second mask 138. The second mask 138 may be applied for instance by lithography or by patterned deposition. The patterned intermediate electrically conductive structure 136 having the homogeneous thickness d2 is then subjected to etching for selectively thinning exposed metallic material of the intermediate electrically conductive structure 136. The etching process may be selected so that the second mask 138 protects metallic material underneath from being removed by etching. After this etching process, the second mask 138 may be removed, for instance by stripping.

The structure shown in FIG. 13 is obtained after the etching and mask removal process described referring to FIG. 12. This treatment leads to patterned electrically conductive structure 110 shown in FIG. 13 having two different connection sections 112, 113 having different thicknesses d1, d2. Connection section 112 with the smaller thickness d1 corresponds to a section of the patterned intermediate electrically conductive structure 136 which has been exposed with respect to the second mask 138 during the etching process described above referring to FIG. 12. Connection section 113 with the larger thickness d2 corresponds to another section of the patterned intermediate electrically conductive structure 136 which has been covered by the second mask 138 during the etching process described above referring to FIG. 12. Hence, FIG. 13 shows the result of the method for forming patterned electrically conductive structure 110 on a main surface of the electrically insulating and thermally conductive sheet 108 so that the patterned electrically conductive structure 110 has two different connection sections 112, 113 having different thicknesses d1, d2.

The skilled person will understand that more than two different connection sections having at least three different thicknesses may be obtained for instance by adding one or more further masking processes.

Again referring to FIGS. 12 and 13, if the second mask 138 is used to cover the right connection structure (with height of d2), then after this treating process (which may be an etching process), the left connection structure may be lower (with height of d1) than the right connection structure (remaining at height of d2). Thus, the masking may be on the finally tallest pillar height d2. Then, one of the connection structures may be etched off by a certain height to reduce its thickness to d1. Optionally, it may be possible to mask again, and then to etch again to create three (or more) different height levels.

FIG. 14 and FIG. 15 shows cross-sectional views of structures obtained during carrying out a method of manufacturing a substrate clip 100 for a package 106 according to another exemplary embodiment.

Referring to FIG. 14, starting point of the manufacturing method may be the provision of a patterned initial electrically conductive structure 150 (for example having a homogeneous thickness d0) on an electrically insulating and thermally conductive sheet 108, for instance made of a ceramic having a homogeneous thickness F. The structure shown in FIG. 14 may be obtained for instance as described above referring to FIG. 10 and FIG. 11.

Referring to FIG. 15, metallic pillars or posts 116, 118 may then be attached to selected surface portions of the initial electrically conductive structure 150 to thereby obtain a patterned electrically conductive structure 110 with different connection sections 112-115 having different thicknesses d0, d1, d2. This may be accomplished by connecting a first metal post 116 and a second metal post 118 having different vertical extensions l1, l2 to different portions of the initial electrically conductive structure 150 of initial thickness d0. This may lead to a first connection section 112 with a thickness d1, a second connection section 113 with a thickness d0, a third connection section 114 (being electrically decoupled from the second connection section 113) with a thickness d0, and a fourth connection section 115 with a thickness d2.

It may also be possible to selectively cover one, some or all connection sections 112-115 with a plating structure 120 at an interface area with an electronic constituent to be connected, for instance a carrier 102 or an electronic component 104. In the shown embodiment, only flange faces of the posts 116, 118 have been covered with plating structure 120.

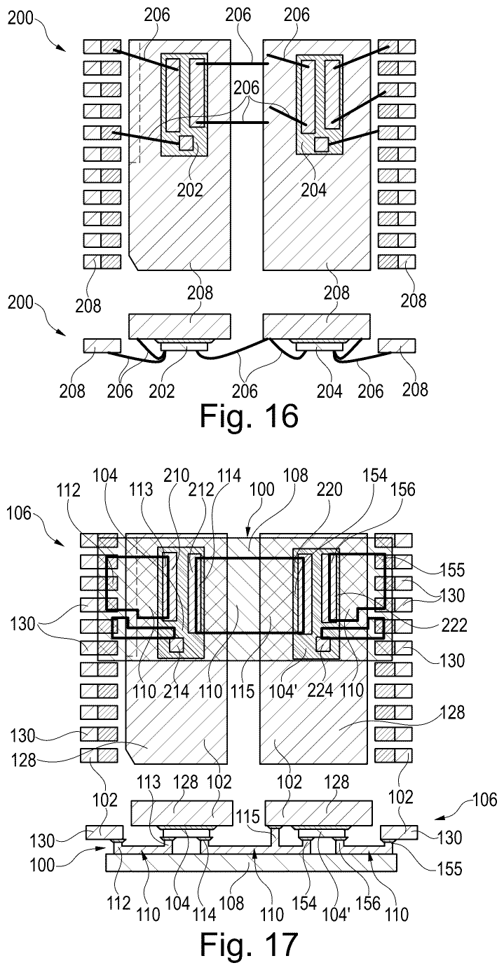

FIG. 16 illustrates a plan view and a cross-sectional view of a conventionally wired half bridge package 200 with electronic components 202, 204 in gallium nitride technology. The electronic components 202, 204 are interconnected by bond wires 206 and are mounted on a carrier 208.

FIG. 17 illustrates a plan view and a cross-sectional view of a half bridge package 106 with a substrate clip 100 and electronic components 104, 104′ in gallium nitride technology according to an exemplary embodiment. In FIG. 17, the interconnection is achieved by substrate clip 100 comprising connection sections 112-115, 154-156. For electronic component 104, the source connection is denoted with reference sign 210, the drain connection is denoted with reference sign 212, and the gate connection is denoted with reference sign 214. For electronic component 104′, the source connection is denoted with reference sign 220, the drain connection is denoted with reference sign 222, and the gate connection is denoted with reference sign 224. This half-bridge configuration has a connection between the source of the high side die to the drain of the low side die, which can be continuously connected.

As can be taken from a comparison of FIG. 16 with FIG. 17, the connection architecture of package 106 can be significantly simplified over package 200.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A substrate clip for connecting a carrier with an electronic component of a package, the substrate clip comprising:
an electrically insulating and thermally conductive sheet; and
a patterned electrically conductive structure on a main surface of the electrically insulating and thermally conductive sheet and having at least two different connection sections having different thicknesses,
wherein a first connection section of the at least two different connection sections, which has a thickness different from a thickness of a second connection section of the at least two different connection sections, is directly connected to an exposed lead section of the carrier,
wherein the second connection section is directly connected to the electronic component.

2. The substrate clip of claim 1, wherein at least one of the at least two different connection sections comprises a metal post.

3. The substrate clip of claim 1, wherein the at least two different connection sections comprise a first metal post and a second metal post having different vertical extensions.

4. The substrate clip of claim 1, wherein the at least two different connection sections comprise a first metallic sheet portion and a second metallic sheet portion having different vertical extensions.

5. The substrate clip of claim 1, wherein at least one of the at least two different connection sections comprises a plating structure at an interface area with the carrier or with the electronic component.

6. The substrate clip of claim 1, wherein:
different ones of the at least two different connection sections are electrically decoupled from each other; and/or
different ones of the at least two different connection sections are electrically coupled with each other.

7. The substrate clip of claim 1, wherein the electrically insulating and thermally conductive sheet is flat with a homogeneous thickness.

8. The substrate clip of claim 1, wherein the electrically insulating and thermally conductive sheet comprises a ceramic.

9. The substrate clip of claim 1, further comprising a further electrically conductive structure, made of solderable material, on an opposing other main surface of the electrically insulating and thermally conductive sheet.

10. The substrate clip of claim 9, wherein the further electrically conductive structure is a continuous layer with a homogeneous thickness.

11. The substrate clip of claim 1, wherein the substrate clip is configured as one of a direct copper bonding-type substrate, a direct aluminum bonding-type substrate, and an active metal brazing-type substrate.

12. A package, comprising:
a carrier;
an electronic component mounted on the carrier; and
the substrate clip of claim 1 connecting the carrier with the electronic component,
wherein at least one of the at least two different connection sections establishes an electrically conductive connection with the carrier,
wherein at least one other one of the at least two different connection sections establishes an electrically conductive connection with the electronic component.

13. The package of claim 12, wherein:
the substrate clip connects at least two different sections of the carrier and/or connects at least two electronic components; and/or
the carrier comprises a component assembly section on which the electronic component is mounted and comprises at least the one lead section electrically coupled with the at least one electronic component and/or with the component assembly section, such that the component assembly section is connected with one of the at least two connection sections and the at least the one lead section is connected with another one of the at least two connection sections.

14. The package of claim 12, wherein:
the main surface of the substrate clip opposing the patterned electrically conductive structure forms part of an exterior surface of the package; and/or
a main surface of the carrier forms part of the exterior surface of the package.

15. The package of claim 12, further comprising an encapsulant encapsulating part of the carrier, at least part of the substrate clip, and at least part of the electronic component, wherein the substrate clip protrudes out of the encapsulant or is coplanar with the encapsulant.

16. The package of claim 12, wherein the electronic component is arranged in a flip chip configuration and has an active region at a front side of the electronic component which is connected with the carrier.

17. The package of claim 12, wherein:
the electronic component and a further electronic component are connected in a half bridge configuration; and/or
the different connection sections have at least three different thicknesses; and/or
the different connection sections have a first thickness connecting the electronic component, a second thickness connecting a further electronic component, and a third thickness connecting the carrier; and/or
the package further comprises at least one further electronic component mounted on the carrier; and/or
the electronic component comprises at least one terminal facing the substrate clip; and/or
the electronic component has at least one terminal on each of both opposing main surfaces thereof; and/or
the electronic component is a vertical electronic component; and/or
the electronic component is a lateral electronic component.

18. A method of manufacturing a substrate clip for connecting a carrier with an electronic component of a package, the method comprising:
providing an electrically insulating and thermally conductive sheet; and
forming a patterned electrically conductive structure on a main surface of the electrically insulating and thermally conductive sheet such that the patterned electrically conductive structure has at least two different connection sections having different thicknesses, wherein a first connection section of the at least two different connection sections, which has a thickness different from a thickness of a second connection section of the at least two different connection sections, is directly connected to an exposed lead section of the carrier, and the second connection section is directly connected to the electronic component.

19. The method of claim 18, wherein forming the patterned electrically conductive structure comprises:
treating an initial electrically conductive structure using a first mask to form an intermediate electrically conductive structure having a homogeneous thickness; and
thereafter treating the intermediate electrically conductive structure using a second mask to obtain the patterned electrically conductive structure with the at least two different connection sections having different thicknesses.

20. The method of claim 18, wherein forming the patterned electrically conductive structure comprises:
providing an initial electrically conductive structure having a homogeneous thickness; and
thereafter attaching at least one post to the initial electrically conductive structure to obtain the patterned electrically conductive structure with the at least two different connection sections having different thicknesses.
